(19) United States
(12) Patent Application Publication
(10) Pub. No.: US 2013/0044408 A1
(43) Pub. Date: Feb. 21, 2013

(54) Docking station

(71) Applicant: Marc Hofer, Oberndorf (AT)

(72) Inventor: Marc Hofer, Oberndorf (AT)

(73) Assignee: IROOM GMBH

(21) Appl. No.: 13/137,476

(22) Filed: Aug. 18, 2011

(51) Int. Cl. H05K 7/00

(52) U.S. Cl. 361/679.01

(57) ABSTRACT

The invention relates to a docking station comprising a first part which is fixable on a base surface, and a movable second part, wherein the movable second part is arranged on the first part and is pivotable relative to the same.

### BACKGROUND OF THE INVENTION

The invention relates to a docking station, in particular for receiving electronic devices such as, for example, tablet computers.

DE 20 2007 000 791 U1 describes a flush-mounted assembly unit for an electric device, the unit comprising a wall box made of plastic and a metallic insert which can be fixed in said wall box for holding the device, wherein a holding apparatus is provided which is fastened to the wall box and on which said insert is attached in an adjustable manner.

EP 2 116 916 A1 discloses a holder comprising a computer receptacle for a calculator, wherein the holder has a supply receptacle for power supply. U.S. Pat. No. 6,188,572 B1 and EP 1 760 712 A1 describe further embodiments of docking stations.

U.S. 2004/0228622 A1 shows a docking station comprising a part that can be fixed on a base surface as well as a part that can be pivoted relative to the fixable part. A similar arrangement can also be found in U.S. 2004/0227372 A1.

The devices disclosed in the prior art have the disadvantage that they have a failure-prone and sometimes complicated structure which requires high dexterity when inserting or removing the electrical device.

### SUMMARY OF THE INVENTION

It is therefore the object of the invention to eliminate the disadvantages of the prior art and to provide a docking station for electronic devices which is easy to operate and, at the same time, has a shapely design.

This object is solved according to the invention by a docking station in that the latter has a first part which is fixable on a base surface, and a second part which is movable, wherein the movable second part is arranged on the first part and is pivotable relative to the same. By pivoting the movable part, a receptacle is exposed into which an electronic device can be plugged, wherein after plugging in the device, the movable second part is pivoted back again into the initial position so that the electrical device is fixed and securely arranged in the docking station according to the invention and, if necessary, can be supplied with electrical energy.

In a preferred embodiment of the invention it is provided that the movable second part is pivotable relative to the first part via a pivot axis which is substantially arranged in the plane of the first part. If the second movable part is smaller than the first part, it is provided in a particularly preferred embodiment of the invention that by pivoting, the movable second part can be arranged in the first part so that said second part is entirely received by the latter.

Particularly preferred, in addition, a proximity switch is provided upon activation of which a pivoting movement of the movable part takes place. Said proximity switch triggers the pivoting movement of the movable part without the need of contacting the docking station.

In order to ensure a particularly quiet and controlled pivoting of the movable second part, in a further variant, an electric motor is provided for the movement of the second part, which electric motor preferably interacts with the proximity switch.

In order to allow a simple removal of the electronic device as well as simple insertion of the same into the docking station according to the invention it is preferably provided that the plane of the movable second part and the plane of the first part enclose a maximum inclination angle of preferably 20°.

The operation of the docking station as well as the function of the same as charging station for electronic devices requires accommodating electronic components in the docking station. To keep their installation height as small as possible it is provided in a preferred embodiment of the invention that the fixable first part is arranged on a flush-mounted box in which these components are accommodated. If, for example, the docking station according to the invention is attached to a wall, only the fixable first part and, as the case may be, the outwardly pivoted second part protrude from the plane of the wall.

The docking station according to the invention has proved itself in particular for the use of charging and/or storing electronic devices, in particular tablet computers such as the iPad®.

### BRIEF DESCRIPTION OF THE DRAWINGS

The invention is illustrated in more detail hereinafter by means of a non-limiting exemplary embodiment with associated figures. In the figures:

FIG. 1 shows a front view of the docking station according to the invention,

FIG. 2a shows a first side view of the docking station from FIG. 1 with the second part being pivoted,

FIG. 2b shows a first side view of the docking station from FIG. 1 with the second part being closed,

FIG. 3a shows a second side view of the docking station from FIG. 1 with the second part being pivoted,

FIG. 3b shows a second side view of the docking station from FIG. 1 with the second part being closed,

FIG. 4 shows a further side view of the docking station from FIG. 1 with the second part being pivoted and an electronic device inserted therein, and

FIG. 5 shows a further side view of the docking station with the second part being closed and with flush-mounted box.

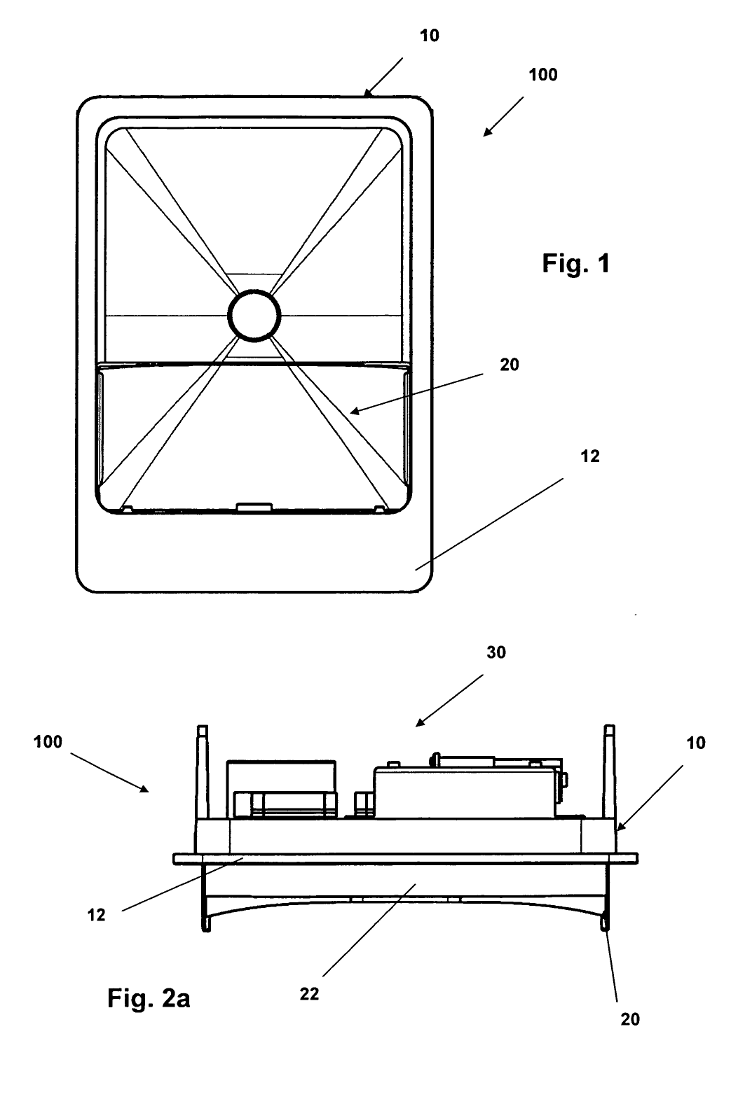

### DETAILED DESCRIPTION OF THE PREFERRED EMBODIMENT

The figures show the docking station 100 according to the invention which consists of first part 10 which is fixable on a base surface as well as a movable second part 20 which is arranged on the fixable first part 10 and is configured in this embodiment as outwardly folding sliding compartment. The first part 10 has an indentation 11 which is provided for receiving an electronic device, for example a tablet computer 200 such as the iPad®.

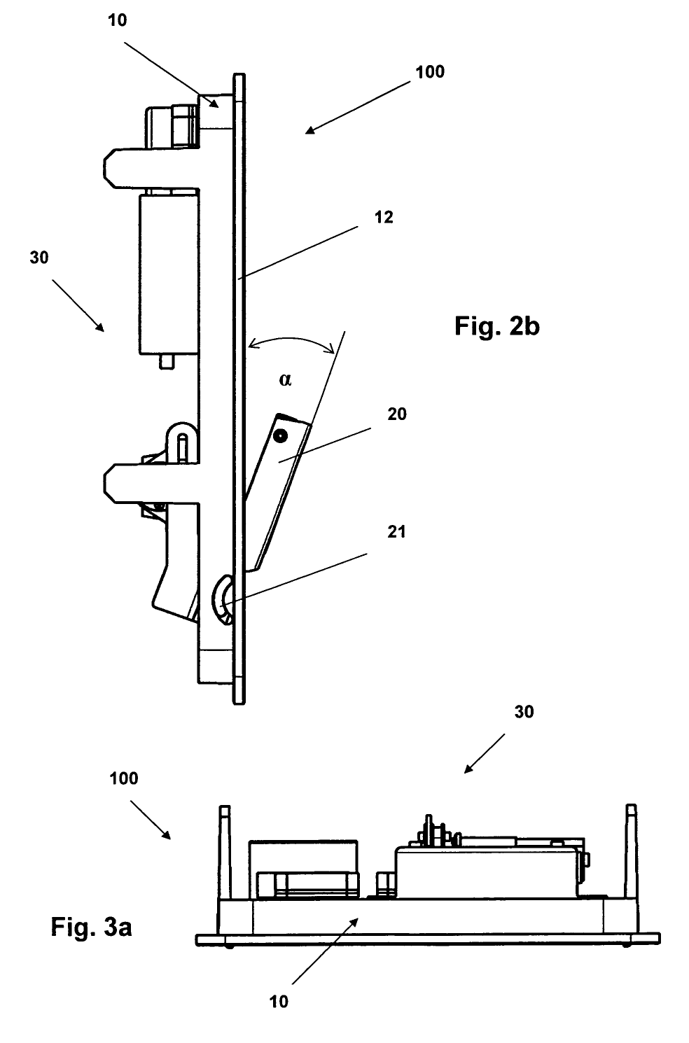

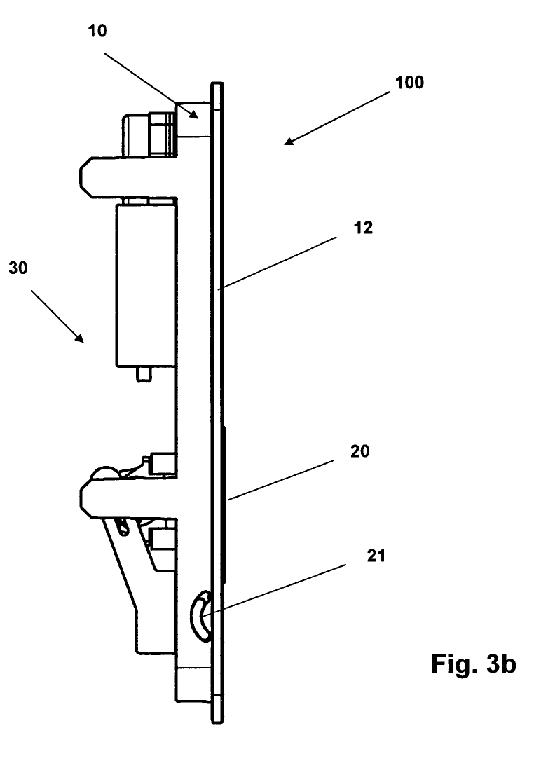

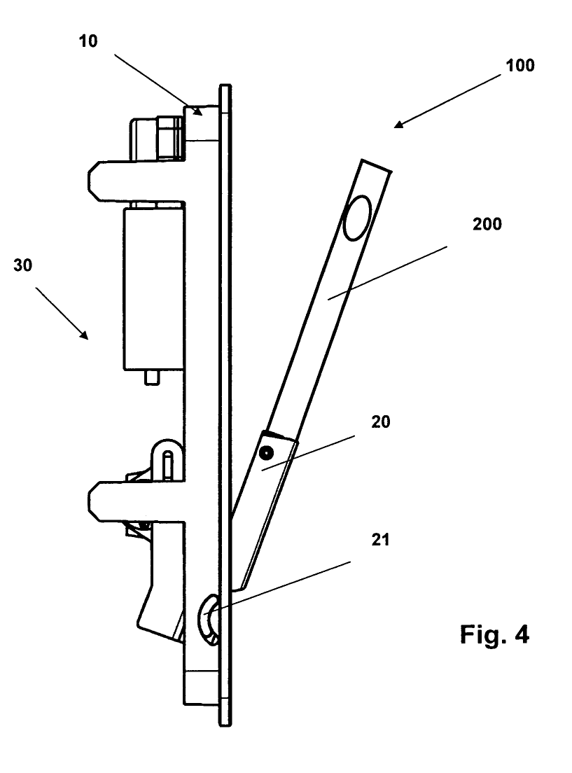

As shown in particular in the FIGS. 2b and 3b, the fixable first part 10 has a front plate 12, for example made of acrylic glass, which e.g. has a thickness of 5 mm. Only this front plate 12 protrudes from the wall or the base surface when the docking station 100 is installed according to the invention. Of course, instead of a wall, it can also be provided that the docking station 100 is arranged on a furniture surface, for example a tabletop.

As shown in particular in the FIGS. 2a and 3a, the movable second part 20 can be pivoted about a pivot axis 21 out of the plane of the first part 10, wherein here, the maximum angle α is 20°, for example.

The pivoting movement of the movable second part 20 is particularly preferred initiated, for example, by a capacitive proximity switch (not shown) which is accommodated, for example, in the front plate 12 of the first part 10. Thus, for example, a movement of a user approximately 5 mm away from the proximity sensor has the effect that the movable second part 20 folds out of the docking station 100 so as to allow the insertion or removal of an electronic device 200. After a predetermined time, for example 20 seconds, the movable part 20 pivots back again into the docking station 100 and in doing so, into the first part 10.

Once the second part 20 is pivoted outward, the electronic apparatus 200 can be plugged or slid into the second part's 20 receptacle 22 exposed in this manner and subsequently, by folding the movable part 20 back in the plane of the first part 10, is arranged in the indentation 11 of the first part 10.

If, by doing so, the electronic device 200 is not correctly inserted, preferably, an overload protection is provided which causes the movable part 20 to fold out, wherein the latter returns again into the closed position according to FIGS. 2b and 3b only after the electronic device 200 has been removed and, if necessary, has been inserted correctly into the receptacle 22.

On the backside of the first part 10, the electronics 30 with associated power supply required for the movement of the second part 20 or for the charging process is accommodated. If an electronic device 200 is inserted into the docking station 100, the electronic components 30 arranged on the backside of the first part 10 provide for supplying the electronic device 200 with electric energy and/or for charging the components' mobile power supply such as, for example, their accumulators.

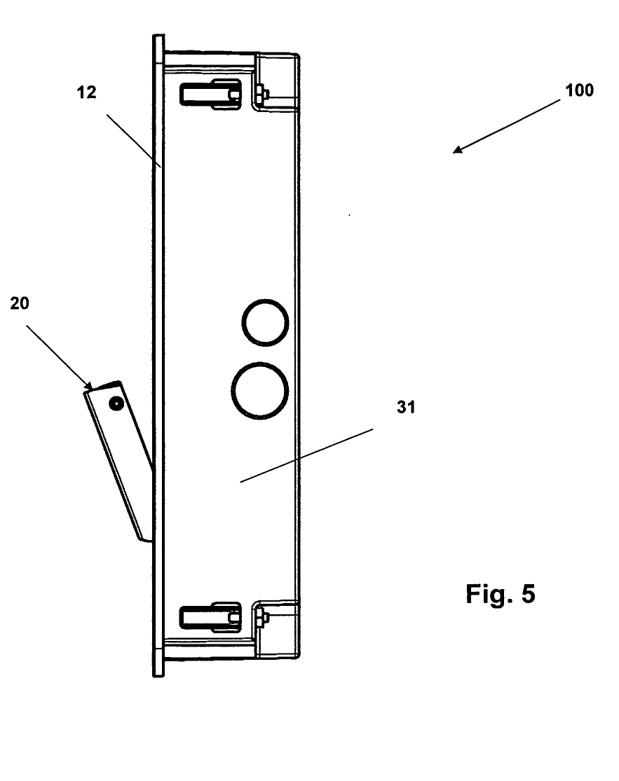

In the described embodiment, the electronics 30 is protected by a flush-mounted box 31 (FIG. 5) which allows the installation of the docking station 100 according to the invention, for example in a wall, in a manner known per se.

As additional protection, the electronics 30 comprises for example a capacitor which in the event of a power failure—thus, when the docking station 100 according to the invention is not supplied with electric current—causes automatic opening by pivoting the movable second part 20 outward so that also in this case, any electronic devices 200 which might be placed in the docking station 100 can be removed.

It is to be understood that the docking station according to the invention is not limited to the use for tablet computers. Likewise, it can also be designed for example for mobile phones, remote controls and other electronic devices which are to be stored in a shapely manner and/or are to be charged. CLAIMS

1. A docking station for an electronic device, characterized by a first part which is fixable on a base surface and by a movable second part for receiving the electronic device, wherein the movable second part is arranged on the first part and is pivotable relative to the latter from a first secured position into a second manipulation position.

2. The docking station according to claim 1, characterized in that the movable second part is pivotable relative to the first part via a pivot axis which is substantially arranged in the plane of the first part.

3. The docking station according to claim 1, characterized in that in addition at least one trigger element is provided upon activation of which a pivoting movement of the movable second part takes place.

4. The docking station according to claim 3, characterized in that the at least one trigger element is configured as proximity switch.

5. The docking station according to claim 3, characterized in that the at least one trigger element is configured as a code keypad which is preferably arranged on the fixable first part.

6. The docking station according to claim 1, characterized in that in addition, a display, in particular a touch screen, is provided which is preferably arranged on the fixable first part.

7. The docking station according to claim 1, characterized in that at least one electric motor for the movement of the movable second part is provided.

8. The docking station according to claim 1, characterized in that the plane of the movable second part and the plane of the first part enclose a maximum inclination angle of preferably 20°.

9. The docking station according to claim 1, characterized in that the fixable first part is arranged in a flush-mounted box.

10. The docking station according to claim 1, characterized in that in addition, a USB interface is provided.

11. The docking station according to claim 1, characterized in that the fixable first part comprises a plug arrangement for supplying electrical power to a device which can be arranged in the docking station.

12. The docking station according to claim 11, characterized in that the plug arrangement can be changed, in particular displaced, with respect to its position.

13. A use of a docking station according to claim 1 for charging and/or storing electronic devices, in particular tablet computers.
